(19) United States
(12) Patent Application Publication
(10) Pub. No.: US 2024/0147608 A1
(43) Pub. Date: May 2, 2024

(54) DISPLAY APPARATUS AND METHOD OF FABRICATING THE SAME

(71) Applicant: AUO Corporation, Hsinchu (TW)

(72) Inventor: Tsung-Ying Ke, Hsinchu (TW)

(73) Assignee: AUO Corporation, Hsinchu (TW)

(21) Appl. No.: 18/088,621

(22) Filed: Dec. 26, 2022

(30) Foreign Application Priority Data
Oct. 28, 2022 (TW) 111141266

(51) Int. Cl. H05K 1/02; H05K 1/18

(52) U.S. Cl. CPC H05K 1/028; H05K 1/189; H05K 2201/10128

(57) ABSTRACT

A display apparatus, including a display panel and a flexible circuit board, is provided. The display panel has a first side and a second side adjacent to each other. The flexible circuit board includes a first part and a second part connected to each other. The first part is electrically bonded to the first side of the display panel. The second part is electrically bonded to the second side of the display panel. The first part of the flexible circuit board is bent along a first bending axis. The second part of the flexible circuit board is bent along a second bending axis. The flexible circuit board is provided with an opening, and an intersection of the first bending axis and the second bending axis overlaps with the opening. A method of fabricating the display apparatus is also provided.

### CROSS-REFERENCE TO RELATED APPLICATION

This application claims the priority benefit of Taiwan application serial no. 111141266, filed on Oct. 28, 2022. The entirety of the above-mentioned patent application is hereby incorporated by reference herein and made a part of this specification.

### BACKGROUND

### Technical Field

The disclosure relates to a display technology, and in particular to a display apparatus and a method of fabricating the same.

### Description of Related Art

In order to implement borderless and seamless splicing display effects, the layout space of signal wire in the peripheral area of the display panel is continuously compressed. Therefore, moving a part of the circuits to a flexible circuit board bonded to the display panel is a conventional option. The bonding range of such flexible circuit board on the display panel has evolved from the previous single side to multiple sides. Therefore, panel driving signals may be transmitted between different sides of the display panel via the flexible circuit board. However, in order to hide the flexible circuit board bonded to the display panel, during the bending process, a part of the flexible circuit board located at the joint between two adjacent sides of the display panel generates excessive deformation that affects the transmission of electrical signals.

### SUMMARY

The disclosure provides a display apparatus, which is suitable for implementing borderless design and seamless splicing display effects.

The disclosure provides a method of fabricating a display apparatus. A bending step of a flexible circuit board thereof is relatively flexible, and an amount of deformation generated on the flexible circuit board is also relatively small.

A display apparatus of the disclosure includes a display panel and a flexible circuit board. The display panel has a first side and a second side adjacent to each other. The flexible circuit board includes a first part and a second part connected to each other. The first part is electrically bonded to the first side of the display panel. The second part is electrically bonded to the second side of the display panel. The first part of the flexible circuit board is bent along a first bending axis. The second part of the flexible circuit board is bent along a second bending axis. The flexible circuit board is provided with an opening, and an intersection of the first bending axis and the second bending axis overlaps with the opening.

A method of fabricating a display apparatus of the disclosure includes the following steps. A bonding process is performed to bond a flexible circuit board to a first side and a second side of a display panel. A first part of the flexible circuit board is bent by 180 degrees along a first bending axis. A second part of the flexible circuit board is bent at an angle greater than or equal to 90 degrees along a second bending axis. The first side is adjacent to the second side. The flexible circuit board includes the first part bonded to the first side, the second part bonded to the second side, and an opening. The first part is connected to the second part.

A display apparatus includes a display panel. The display panel has a display portion and a peripheral portion. The display portion has a first side edge and a second side edge adjacent to each other. The peripheral portion includes a first part extending from the first side edge of the display portion and a second part extending from the second side edge of the display portion. The first part of the peripheral portion is bent along a first bending axis. The second part of the peripheral portion is bent along a second bending axis. The peripheral portion is provided with an opening. An intersection of the first bending axis and the second bending axis overlaps with the opening.

Based on the above, in the display apparatus according to an embodiment of the disclosure, the two parts of the flexible circuit board bonded to the two adjacent sides of the display panel are respectively bent along the two bending axes intersecting each other. Through configuring the openings at the intersection of the two bending axes, excessive deformation that affects the normal operation of the flexible circuit board generated at a junction of the two parts of the flexible circuit board when the two parts are bent can be effectively reduced.

### BRIEF DESCRIPTION OF THE DRAWINGS

FIG. 1A to FIG. 1C are schematic front views of a fabricating process of a display apparatus according to a first embodiment of the disclosure.

FIG. 2 is a schematic rear view of the display apparatus of FIG. 1C.

FIG. 3A to FIG. 3D are schematic cross-sectional views of the fabricating process of the display apparatus according to the first embodiment of the disclosure.

FIG. 4 is a schematic side view of the display apparatus of FIG. 1C.

FIG. 5A to FIG. 5C are schematic front views of a fabricating process of a display apparatus according to a second embodiment of the disclosure.

FIG. 6 is a schematic rear view of the display apparatus of FIG. 5C.

FIG. 7A to FIG. 7D are schematic cross-sectional views of the fabricating process of the display apparatus according to the second embodiment of the disclosure.

FIG. 8 is a schematic side view of the display apparatus of FIG. 5C.

FIG. 9 is a schematic side view of a display apparatus according to a third embodiment of the disclosure.

FIG. 10 is a schematic front view of a display apparatus according to a fourth embodiment of the disclosure.

FIG. 11 and FIG. 12 are schematic front views of a display apparatus according to a fifth embodiment of the disclosure.

### DETAILED DESCRIPTION OF DISCLOSED EMBODIMENTS

As used herein, “about”, “approximately”, “essentially”, or “substantially” includes the stated value and an average value within an acceptable deviation range of the particular value as determined by persons skilled in the art, while taking into account the measurement in discussion and the particular amount of error associated with the measurement (that is, the limitation of a measurement system). For example, “about” may mean within one or more standard deviations or within, for example, ±30%, ±20%, ±15%, ±10%, or ±5% of the stated value. Furthermore, “about”, “approximately”, “essentially”, or “substantially” used herein may choose a more acceptable deviation range or standard deviation according to measurement properties, cutting properties, or other properties and may not apply one standard deviation to all properties.

In the drawings, the thickness of layers, films, panels, regions, etc., is exaggerated for clarity. It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” may be that there is another element between two elements.

In addition, relative terms such as “lower” or “bottom” and “upper” or “top” may be used herein to describe the relationship between an element and another element, as shown in the drawings. It should be understood that the relative terms are intended to include different orientations of a device in addition to the orientations shown in the drawings. For example, if the device in a drawing is flipped, an element described as being on the “lower” side of other elements will be oriented on the “upper” side of the other elements. Therefore, the exemplary term “lower” may include the orientations of “lower” and “upper”, depending on the specific orientation of the drawing. Similarly, if the device in a drawing is flipped, an element described as “below” other elements will be oriented “above” the other elements. Therefore, the exemplary terms “on” and “under” may include the orientations of “above” and “below”.

The exemplary embodiments are described herein with reference to cross-sectional views that are schematic views of idealized embodiments. Therefore, changes in shapes of illustration as a result of, for example, fabricating technology and/or tolerances may be expected. Therefore, the embodiments described herein should not be interpreted as being limited to the specific shapes of regions as shown herein, but include, for example, shape deviations caused by fabrication. For example, a region that is shown or described as flat may generally have rough and/or non-linear features. In addition, an acute angle shown may be rounded. Therefore, the regions shown in the drawings are essentially schematic, and the shapes thereof are not intended to show the precise shapes of the regions and are not intended to limit the scope of the claims.

Reference will now be made in detail to the exemplary embodiments of the disclosure, and examples of the exemplary embodiments are illustrated in the drawings. Wherever possible, the same reference numerals are used in the drawings and descriptions to represent the same or similar parts.

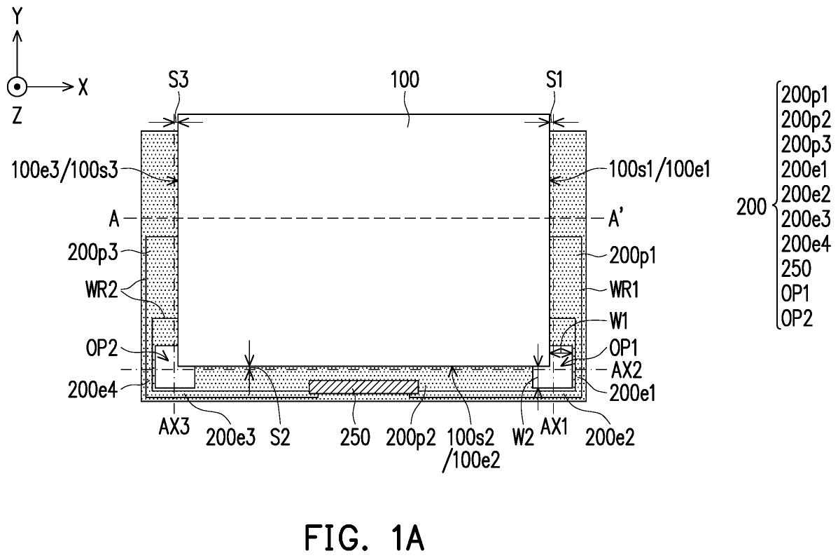

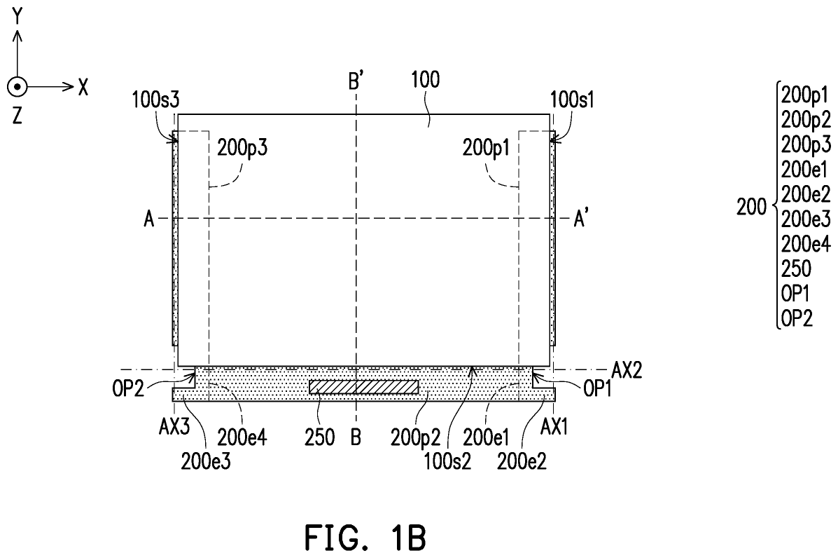

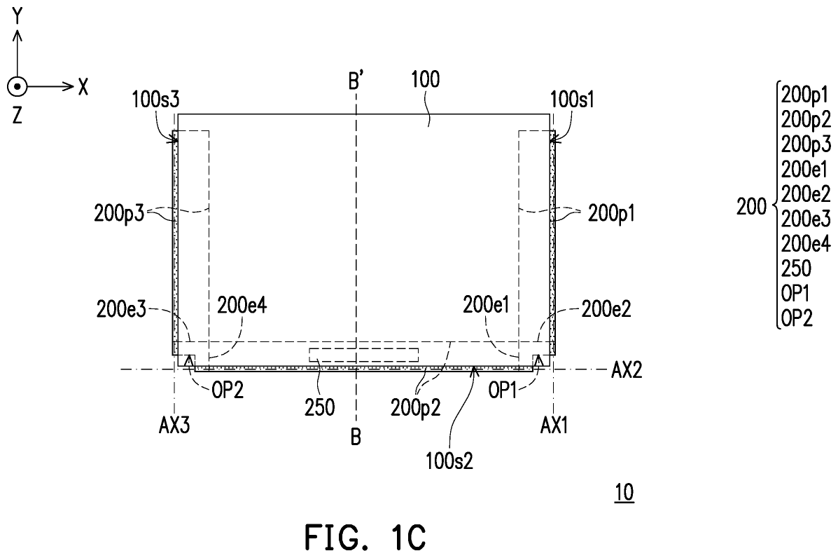

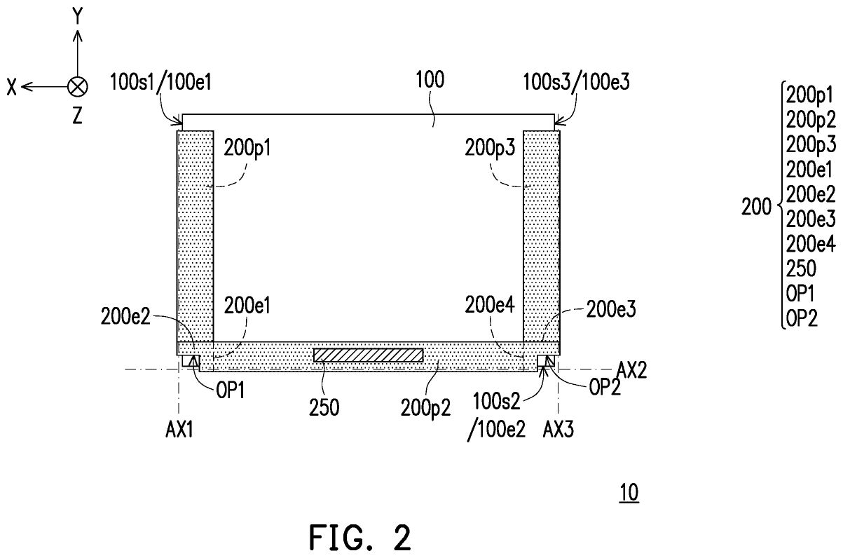

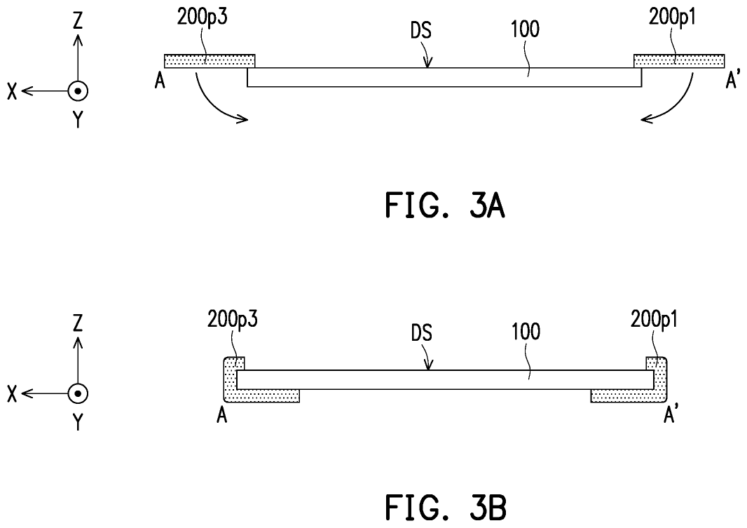

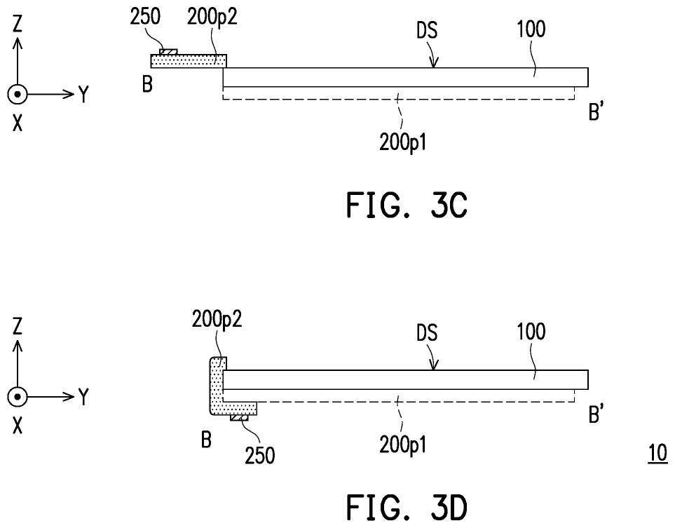

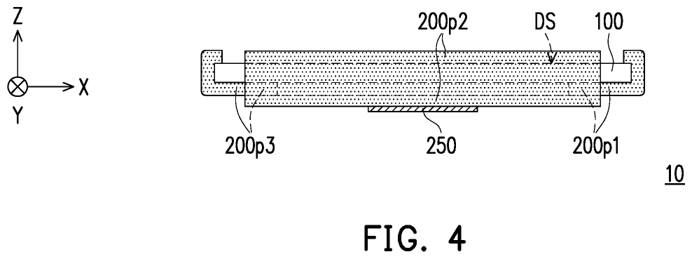

FIG. 1A to FIG. 1C are schematic front views of a fabricating process of a display apparatus according to a first embodiment of the disclosure. FIG. 2 is a schematic rear view of the display apparatus of FIG. 1C. FIG. 3A to FIG. 3D are schematic cross-sectional views of the fabricating process of the display apparatus according to the first embodiment of the disclosure. FIG. 4 is a schematic side view of the display apparatus of FIG. 1C. FIG. 3A and FIG. 3B correspond to a section line A-A′ of FIG. 1A and FIG. 1B. FIG. 3C and FIG. 3D correspond to a section line B-B′ of FIG. 1B and FIG. 1C. For clarity, FIG. 1B, FIG. 1C, and FIG. 2 omit the illustration of a signal wire WR1 and a signal wire WR2 in FIG. 1A.

Please refer to FIG. 1C and FIG. 2. A display apparatus 10 includes a display panel 100 and a flexible circuit board 200. The display panel 100 has a first side 100s1, a second side 100s2, and a third side 100s3. The first side 100s1 is opposite to the third side 100s3 along a direction X. The second side 100s2 is a side of the display panel 100 along a direction Y and is adjacent to the first side 100s1 and the third side 100s3. In the embodiment, the flexible circuit board 200 includes a first part 200p1, a second part 200p2, and a third part 200p3, but not limited thereto. The first part 200p1, the second part 200p2, and the third part 200p3 are respectively electrically bonded to the first side 100s1, the second side 100s2, and the third side 100s3 of the display panel 100.

In the embodiment, the second part 200p2 of the flexible circuit board 200 may be provided with a driving chip 250, and the driving chip 250 is, for example, a source integrated circuit (IC), a gate IC, or other driving chips with different functions, but not limited thereto. In the embodiment, the display panel 100 respectively has a first side edge 100e1, a second side edge 100e2, and a third side edge 100e3 on the first side 100s1, the second side 100s2, and the third side 100s3. It should be noted that the flexible circuit board 200 is provided with an opening OP1 and an opening OP2. The opening OP1 exposes a junction of the first side edge 100e1 and the second side edge 100e2 of the display panel 100. The opening OP2 exposes a junction of the second side edge 100e2 and the third side edge 100e3 of the display panel 100.

In the embodiment, the flexible circuit board 200 further includes a first extension section 200e1 extending from the first part 200p1, a second extension section 200e2 and a third extension section 200e3 extending from the second part 200p2, and a fourth extension section 200e4 extending from the third part 200p3. The first extension section 200e1 is connected to the second extension section 200e2 and is structurally separated from the display panel 100. The third extension section 200e3 is connected to the fourth extension section 200e4 and is structurally separated from the display panel 100.

From another point of view, the first part 200p1, the second part 200p2, the first extension section 200e1, and the second extension section 200e2 define the opening OP1 of the flexible circuit board 200. The second part 200p2, the third part 200p3, the third extension section 200e3, and the fourth extension section 200e4 define the opening OP2 of the flexible circuit board 200 (as shown by the flexible circuit board 200 before being bent in FIG. 1A).

For example, a part of the signal wire WR1 on the second part 200p2 of the flexible circuit board 200 may extend to the first part 200p1 via the first extension section 200e1 and the second extension section 200e2, and another part of the signal wire WR2 may extend to the third part 200p3 via the third extension section 200e3 and the fourth extension section 200e4 (as shown in FIG. 1A). It should be noted that the number of each of the signal wire WR1 and the signal wire WR2 shown in FIG. 1A is exemplified as two for illustration, which does not mean that the disclosure is limited by the content disclosed in the drawing. The number of signal wires may be adjusted according to actual application requirements.

Through the configuration of the extension sections, the layout of peripheral circuits of the display panel 100 can be more flexible. For example, the signal wires originally arranged in a peripheral area (not shown) of the display panel 100 and extending on the two adjacent sides may be changed to being disposed on the flexible circuit board 200. Accordingly, the layout space of peripheral wires of the display panel 100 is reduced, which facilitates the implementation of an ultra-narrow border or borderless appearance design of the display apparatus 10.

It should be noted first that the configuration of the openings can effectively reduce excessive deformation that affects the normal operation (for example, the transmission of electrical signals) of the flexible circuit board 200 generated at a junction of the two adjacent parts (for example, the first part 200p1 and the second part 200p2 or the second part 200p2 and the third part 200p3) of the flexible circuit board 200 when the two parts are bent.

The following will exemplarily illustrate the fabricating process of the display apparatus 10 and will especially describe in detail the fabricating steps after the flexible circuit board 200 and the display panel 100 are electrically bonded.

Please refer to FIG. 1A. A bonding process is performed to bond the flexible circuit board 200 to the first side 100s1, the second side 100s2, and the third side 100s3 of the display panel 100. The first side 100s1, the second side 100s2, and the third side 100s3 of the display panel 100 are respectively bonded with the first part 200p1, the second part 200p2, and the third part 200p3 of the flexible circuit board 200.

In the embodiment, the first part 200p1, the second part 200p2, and the third part 200p3 of the flexible circuit board 200 are respectively adapted to be bent along a first bending axis AX1, a second bending axis AX2, and a third bending axis AX3. It should be noted that extension paths of the bending axes pass through the opening OP1 and the opening OP2 on the flexible circuit board 200. For example, the opening OP1 overlaps with an intersection of the first bending axis AX1 and the second bending axis AX2 along a direction Z, and the opening OP2 overlaps with an intersection of the second bending axis AX2 and the third bending axis AX3 along the direction Z.

During a folding process of the flexible circuit board 200, through the above configuration relationship, the number of bending of each part (for example, the first part 200p1 to the third part 200p3 and the first extension section 200e1 to the fourth extension section 200e4) can be controlled at one time, so as to effectively prevent excessive deformation that affects the transmission of electrical signals at the surrounding part (for example, the first extension section 200e1 to the fourth extension section 200e4) from being generated at the part of the flexible circuit board 200 near the junction of the two adjacent side edges of the display panel 100 (that is, the part of the conventional flexible circuit board that overlaps with the openings).

On the other hand, there is a first spacing S1 between the first bending axis AX1 and the first side edge 100e1 of the display panel 100 in the direction X. There is a second spacing S2 between the second bending axis AX2 and the second side edge 100e2 of the display panel 100 in the direction Y. There is a third spacing S3 between the third bending axis AX3 and the third side edge 100e3 of the display panel 100 in the direction X. For example, each of the spacings (that is, bending radii) may be less than or equal to 0.1 mm, so as to satisfy the seamless splicing display effect of multiple display apparatuses 10.

From another point of view, in the embodiment, the opening OP1 at the junction of the first side edge 100e1 and the second side edge 100e2 of the display panel 100 is exposed, and a minimum width W1 thereof along the direction X is greater than the first spacing S1, so that the first bending axis AX1 can pass through the opening OP1. A minimum width W2 of the opening OP1 along the direction Y must be greater than the second spacing S2, so that the second bending axis AX2 can pass through the opening OP1. Since the relative relationship between the minimum widths of the opening OP2 in different directions and the second spacing S2 and the third spacing S3 is similar to the design principle of the opening OP1, details will not be repeated here.

Please refer to FIG. 1A, FIG. 1B, and FIG. 3A. After completing the bonding process, a folding step of the flexible circuit board 200 is performed. For example, in the embodiment, the folding step of the flexible circuit board 200 includes bending the first part 200p1 of the flexible circuit board 200 by 180 degrees along the first bending axis AX1, so that the first part 200p1 is accommodated on a side (that is, a back side) of the display panel 100 away from a display surface DS, and bending the third part 200p3 of the flexible circuit board 200 by 180 degrees along the third bending axis AX3, so that the third part 200p3 is accommodated on the back side of the display panel 100, as shown in FIG. 3B.

It should be noted that after completing the bending step of the first part 200p1 and the third part 200p3 of the flexible circuit board 200, each of the first extension section 200e1 and the fourth extension section 200e4 overlaps with the second part 200p2 along the direction Z (as shown in FIG. 1B).

Please refer to FIG. 3C. In the embodiment, the folding step of the flexible circuit board 200 further includes after bending the first part 200p1 and the third part 200p3, bending the second part 200p2 of the flexible circuit board 200 by 180 degrees along the second bending axis AX2, so that the second part 200p2 is accommodated on the back side (that is, the side away from the display surface DS) of the display panel 100, as shown in FIG. 1C and FIG. 3D.

Since the bending step of the first part 200p1 and the third part 200p3 of the flexible circuit board 200 is before the bending step of the second part 200p2, after completing the folding step of the flexible circuit board 200, the part of the first part 200p1 and the third part 200p3 folded onto the back side of the display panel 100 is located between the part of the second part 200p2 folded onto the back side of the display panel 100 and the display panel 100 (as shown in FIG. 3D and FIG. 4), but not limited thereto.

It should be noted that after completing the bending step of the second part 200p2 of the flexible circuit board 200, the second extension section 200e2 and the third extension section 200e3 of the flexible circuit board 200 respectively overlap with the first part 200p1 and the third part 200p3 along the direction Z (as shown in FIG. 1C). Here, the fabrication of the display apparatus 10 is completed.

In the display apparatus 10 completed based on the above fabricating process, the flexible circuit board 200 accommodated on the back side of the display panel 100 is provided with the opening OP1 at the junction of the first side edge 100e1 and the second side edge 100e2 of the display panel 100 and is provided with another opening OP2 at the junction of the second side edge 100e2 and the third side edge 100e3 of the display panel 100. The configuration of the openings can prevent excessive deformation that affects the normal operation of the flexible circuit board 200 from being generated at the junction of the two adjacent parts of the flexible circuit board 200.

Some other embodiments will be listed below to describe the disclosure in detail, wherein the same components will be marked with the same reference numerals, and the description of the same technical content will be omitted. For the omitted part, please refer to the foregoing embodiment, and there will be no reiteration below.

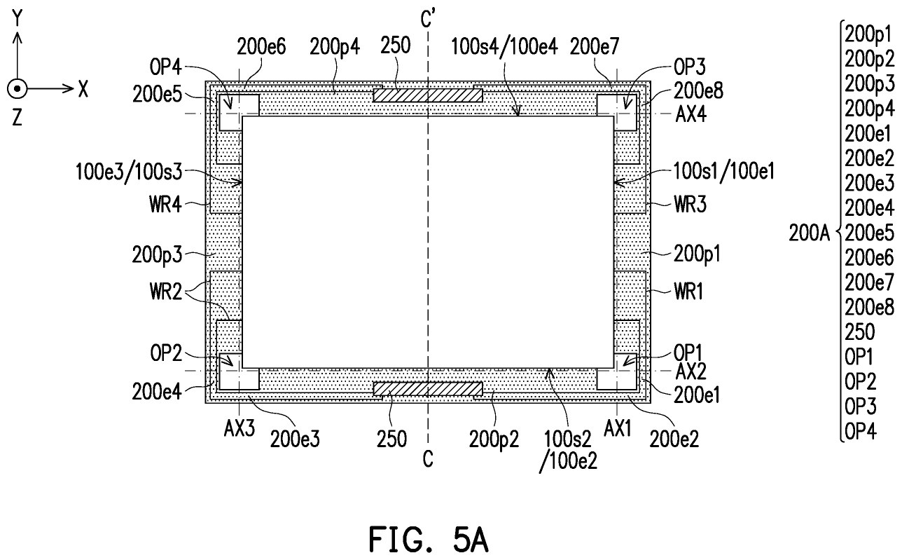

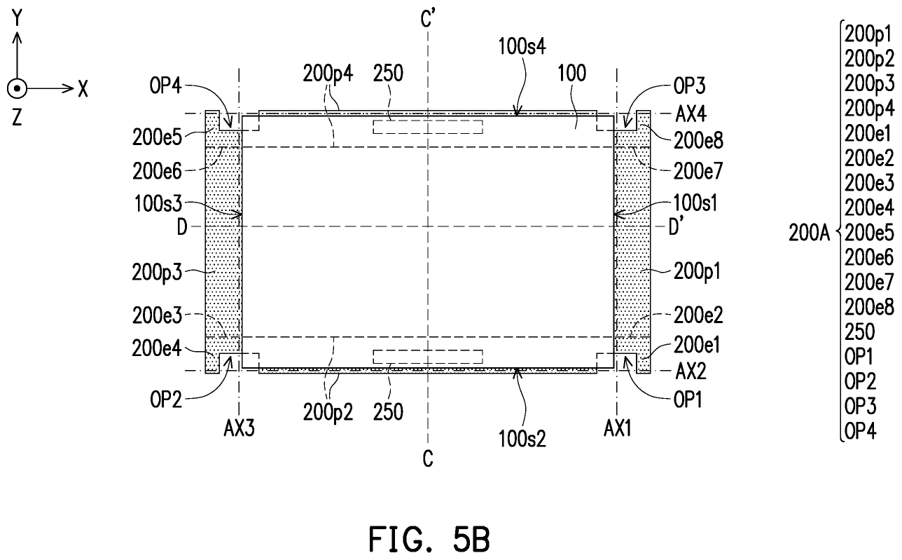

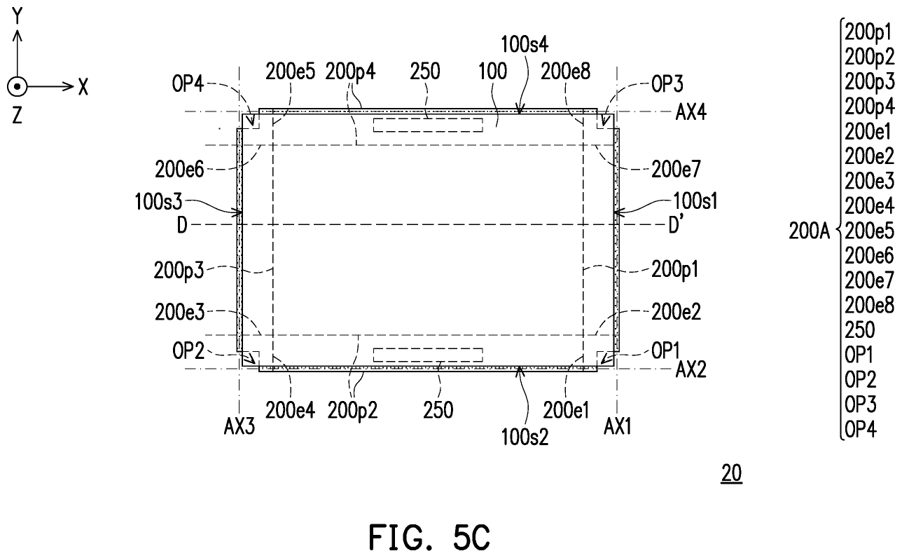

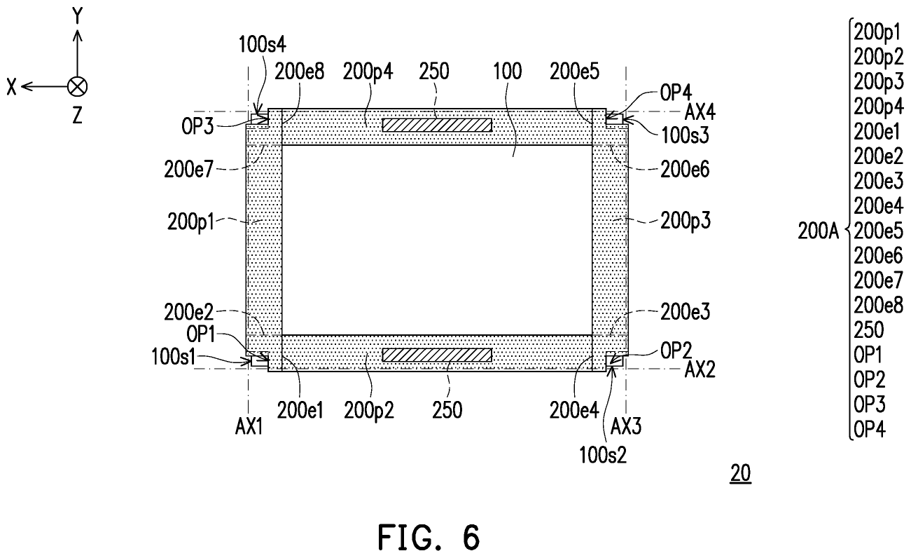

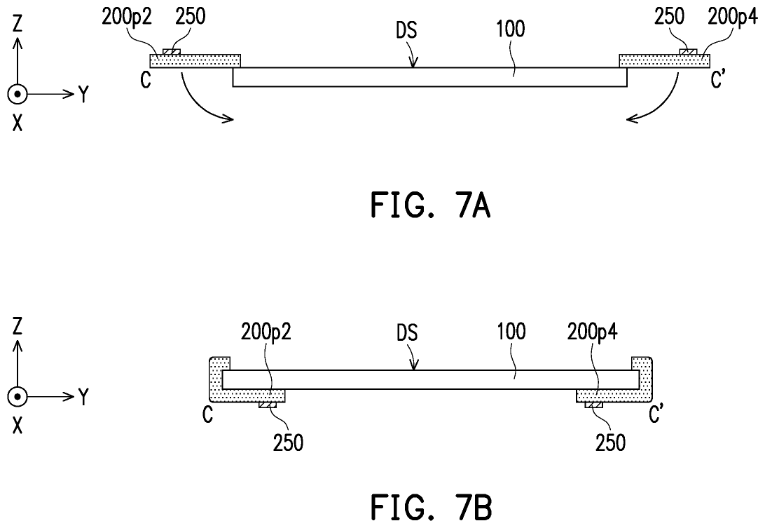

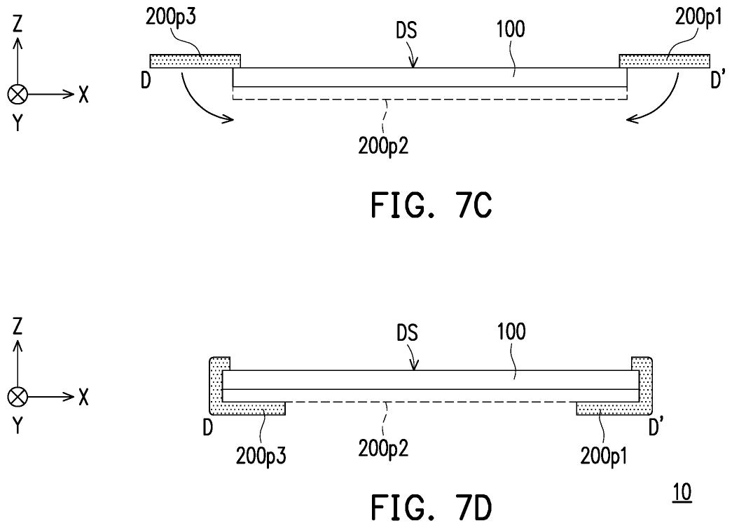

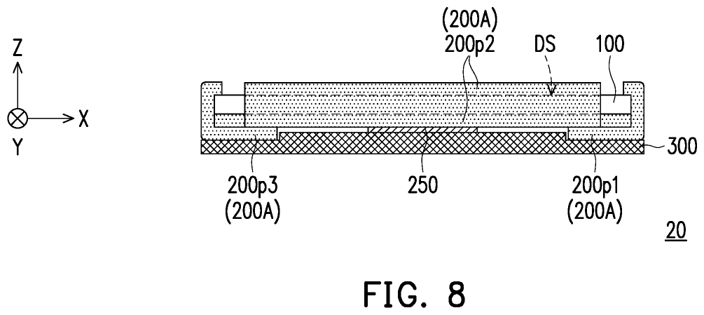

FIG. 5A to FIG. 5C are schematic front views of a fabricating process of a display apparatus according to a second embodiment of the disclosure. FIG. 6 is a schematic rear view of the display apparatus of FIG. 5C. FIG. 7A to FIG. 7D are schematic cross-sectional views of the fabricating process of the display apparatus according to the second embodiment of the disclosure. FIG. 8 is a schematic side view of the display apparatus of FIG. 5C. FIG. 7A and FIG. 7B correspond to a section line C-C′ of FIG. 5A and FIG. 5B. FIG. 7C and FIG. 7D correspond to a section line D-D′ of FIG. 5B and FIG. 5C. For the sake of clarity, FIG. 5B, FIG. 5C and FIG. 6 omit the illustration of the signal wire WR1 to the signal wire WR4 in FIG. 5A.

Please refer to FIG. 5A and FIG. 1A. The difference between a flexible circuit board 200A of the embodiment and the flexible circuit board 200 of FIG. 1A is that the flexible circuit board 200A of the embodiment further has a fourth part 200p4 electrically bonded to a fourth side 100s4 of the display panel 100, wherein the fourth side 100s4 of the display panel 100 is opposite to the third side 100s3 along the direction Y and is adjacent to the first side 100s1 and the second side 100s2. On the other hand, the folding step of the flexible circuit board 200A of the embodiment is also different from the flexible circuit board 200 of FIG. 1A.

Similar to the configuration relationship between the second part 200p2 and the first part 200p1 (or the third part 200p3) of the flexible circuit board 200A, the flexible circuit board 200A of the embodiment may also be provided with the driving chip 250 on the fourth part 200p4 and may be provided with an opening OP3 at where the fourth part 200p4 is adjacent to the first part 200p1 and provided with an opening OP4 at where the fourth part 200p4 is adjacent to the third part 200p3.

In the embodiment, the opening OP3 exposes the junction of the first side edge 100e1 of the display panel 100 and a fourth side edge 100e4 at the fourth side 100s4 of the display panel 100. The opening OP4 exposes the junction of the third side edge 100e3 and the fourth side edge 100e4 of the display panel 100. In addition, the flexible circuit board 200A further includes a fifth extension section 200e5 extending from the third part 200p3, a sixth extension section 200e6 and a seventh extension section 200e7 extending from the fourth part 200p4, and an eighth extension section 200e8 extending from the first part 200p1. The fifth extension section 200e5 is connected to the sixth extension section 200e6 and is structurally separated from the display panel 100. The seventh extension section 200e7 is connected to the eighth extension section 200e8 and is structurally separated from the display panel 100.

From another point of view, the first part 200p1, the fourth part 200p4, the seventh extension section 200e7, and the eighth extension section 200e8 define the opening OP3 of the flexible circuit board 200A. The fourth part 200p4, the third part 200p3, the fifth extension section 200e5, and the sixth extension section 200e6 define the opening OP4 of the flexible circuit board 200A (as shown by the flexible circuit board 200A before being bent in FIG. 5A).

Similar to the signal wire of the flexible circuit board 200A on the second part 200p2 that may extend to the adjacent part via the corresponding extension section, a part of a signal wire WR3 of the flexible circuit board 200A on the fourth part 200p4 of the embodiment may extend to the first part 200p1 via the seventh extension section 200e7 and the eighth extension section 200e8, and another part of a signal wire WR4 may extend to the third part 200p3 via the fifth extension section 200e5 and the sixth extension section 200e6 (as shown in FIG. 5A).

Through the configuration of the extension sections, the layout of the peripheral circuits of the display panel 100 can be more flexible. For example, the signal wires originally arranged in the peripheral area (not shown) of the display panel 100 and extending on the two adjacent sides may be changed to being disposed on the flexible circuit board 200A. Accordingly, the layout space of the peripheral wires of the display panel 100 is reduced, which facilitates the implementation of an ultra-narrow border or borderless appearance design of a display apparatus 20 (as shown in FIG. 5C).

On the other hand, the configuration of the openings can effectively reduce excessive deformation that affects the normal operation (for example, the transmission of electrical signals) of the flexible circuit board 200A generated at the junction of the two adjacent parts (for example, the first part 200p1 and the second part 200p2, the second part 200p2 and the third part 200p3, the third part 200p3 and the fourth part 200p4, or the fourth part 200p4 and the first part 200p1) of the flexible circuit board 200A when the two parts are bent.

The following will exemplarily illustrate the fabricating process of the display apparatus 20 and will especially describe in detail the fabricating steps after the flexible circuit board 200A and the display panel 100 are electrically bonded.

Please refer to FIG. 5A. The bonding process is performed, so that the flexible circuit board 200A is bonded to the first side 100s1, the second side 100s2, the third side 100s3, and the fourth side 100s4 of the display panel 100. The first side 100s1, the second side 100s2, the third side 100s3, and the fourth side 100s4 of the display panel 100 are respectively bonded with the first part 200p1, the second part 200p2, the third part 200p3, and the fourth part 200p4 of the flexible circuit board 200A.

In the embodiment, the first part 200p1, the second part 200p2, the third part 200p3, and the fourth part 200p4 of the flexible circuit board 200A are respectively adapted to be bent along the first bending axis AX1, the second bending axis AX2, the third bending axis AX3, and a fourth bending axis AX4. It should be noted that extension paths of the bending axes pass through the opening OP1, the opening OP2, the opening OP3, and the opening OP4 on the flexible circuit board 200A. For example, the opening OP1 overlaps with the intersection of the first bending axis AX1 and the second bending axis AX2 along the direction Z. The opening OP2 overlaps with the intersection of the second bending axis AX2 and the third bending axis AX3 along the direction Z. The opening OP3 overlaps with an intersection of the first bending axis AX1 and the fourth bending axis AX4 along the direction Z. The opening OP4 overlaps with an intersection of the third bending axis AX3 and the fourth bending axis AX4 along the direction Z.

During the folding process of the flexible circuit board 200A, through the above configuration relationship, the number of bending of each part (for example, the first part 200p1 to the fourth part 200p4 and the first extension section 200e1 to the eighth extension section 200e8) can be controlled at one time, so as to effectively prevent excessive deformation that affects the transmission of electrical signals at the surrounding part (for example, the first extension section 200e1 to the eighth extension section 200e8) from being generated at the part of the flexible circuit board 200A near the junction of the two adjacent side edges of the display panel 100 (that is, the part of the conventional flexible circuit board that overlaps with the openings).

Since the configuration relationship among the openings, the bending axes, and the display panel 100 of the embodiment is similar to the configuration relationship among the openings, the bending axes, and the display panel 100 of FIG. 1A, for detailed description, please refer to the relevant paragraphs of the foregoing embodiment, and there will be no reiteration here.

It should be explained first that, different from the folding process of the flexible circuit board 200 of FIG. 1A during which the part without the driving chip 250 is bent first, during the folding process of the flexible circuit board 200A of the embodiment, the part provided with the driving chip 250 is bent first.

Please refer to FIG. 5A, FIG. 5B, and FIG. 7A. After completing the bonding process, the folding step of the flexible circuit board 200A is performed. For example, in the embodiment, the folding step of the flexible circuit board 200A includes bending the second part 200p2 of the flexible circuit board 200A by 180 degrees along the second bending axis AX2, so that the second part 200p2 is accommodated on the side (that is, the back side) of the display panel 100 away from the display surface DS, and bending the fourth part 200p4 of the flexible circuit board 200A by 180 degrees along the fourth bending axis AX4, so that the fourth part 200p4 is accommodated on the back side of the display panel 100, as shown in FIG. 7B.

It should be noted that after completing the bending step of the second part 200p2 and the fourth part 200p4 of the flexible circuit board 200A, each of the second extension section 200e2 and the seventh extension section 200e7 overlaps with the first part 200p1 along the direction Z, and each of the third extension section 200e3 and the sixth extension section 200e6 overlaps with the third part 200p3 along the direction Z (as shown in FIG. 5B).

Please refer to FIG. 5C, FIG. 7C, and FIG. 7D. In the embodiment, the folding step of the flexible circuit board 200A further includes after bending the second part 200p2 and the fourth part 200p4, the first part 200p1 of the flexible circuit board 200A is bent by 180 degrees along the first bending axis AX1, so that the first part 200p1 is accommodated on the back side (that is, the side away from the display surface DS) of the display panel 100, and the third part 200p3 of the flexible circuit board 200A is bent by 180 degrees along the third bending axis AX3, so that the third part 200p3 is accommodated on the back side of the display panel 100.

Different from the display apparatus 10 of FIG. 4, in the embodiment, since the bending step of the second part 200p2 and the fourth part 200p4 of the flexible circuit board 200A are before the bending step of the first part 200p1 and the third part 200p3, after completing the folding step of the flexible circuit board 200A, the part of the second part 200p2 and the fourth part 200p4 folded onto the back side of the display panel 100 is located between the part of the first part 200p1 and the third part 200p3 folded onto the back side of the display panel 100 and the display panel 100 (as shown in FIG. 7D and FIG. 8), but not limited thereto.

It should be noted that after completing the bending step of the first part 200p1 and the third part 200p3 of the flexible circuit board 200A, the first extension section 200e1 and the fourth extension section 200e4 of the flexible circuit board 200A overlap with the second part 200p2 along the direction Z, and the fifth extension section 200e5 and the eighth extension section 200e8 of the flexible circuit board 200A overlap with the fourth part 200p4 along the direction Z (as shown in FIG. 5C). Here, the fabrication of the display apparatus 20 is completed.

In the display apparatus 20 completed based on the above fabricating process, the flexible circuit board 200A accommodated on the back side of the display panel 100 is respectively provided with the opening OP1, the opening OP2, the opening OP3, and the opening OP4 at the junction of the first side edge 100e1 and the second side edge 100e2 of the display panel 100, the junction of the second side edge 100e2 and the third side edge 100e3, the junction of the third side edge 100e3 and the fourth side edge 100e4, and the junction of the fourth side edge 100e4 and the first side edge 100e1. The configuration of the openings can prevent excessive deformation that affects the normal operation of the flexible circuit board 200A from being generated at the junction of the two adjacent parts of the flexible circuit board 200A.

In the embodiment, the display apparatus 20 may further include a back frame 300 (as shown in FIG. 8) for fixing the display panel 100 on which the flexible circuit board 200A is accommodated, but the disclosure is not limited thereto.

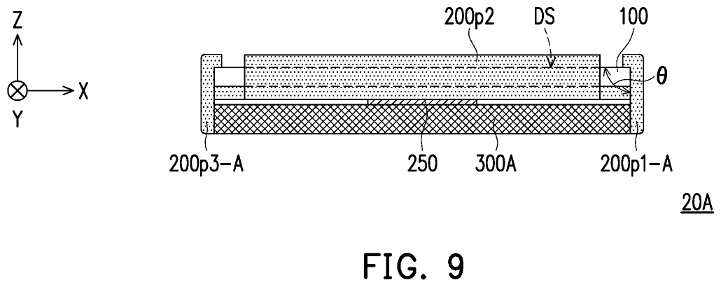

FIG. 9 is a schematic side view of a display apparatus according to a third embodiment of the disclosure. Please refer to FIG. 9. Different from the flexible circuit board 200A of the display apparatus 20 of FIG. 8 in which the first part 200p1 and the third part 200p3 are folded onto the back side (that is, the side away from the display surface DS) of the display panel 100 at an angle of 180 degrees, a first part 200p1-A and a third part 200p3-A of a flexible circuit board of the embodiment are folded onto the back side of the display panel 100 at a bending angle of 90 degrees.

The bending angle here is, for example, an angle θ between a bent section of the first part 200p1-A and the display surface DS of the display panel 100. However, the disclosure is not limited thereto. In other embodiments, the angle θ may also be greater than 90 degrees and less than 180 degrees.

In order to accommodate the first part 200p1-A and the third part 200p3-A of the flexible circuit board folded at 90 degrees, the structure of a back frame 300A of the embodiment is also different from the back frame 300 of FIG. 8.

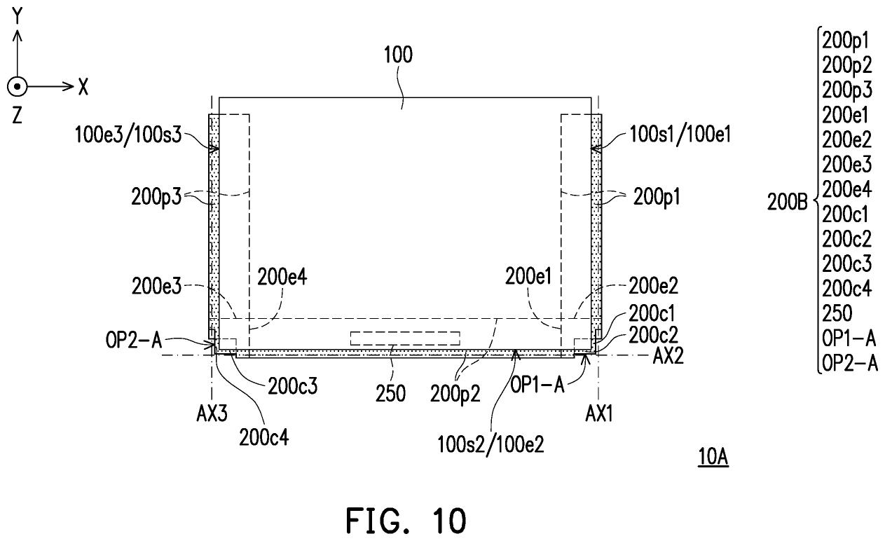

FIG. 10 is a schematic front view of a display apparatus according to a fourth embodiment of the disclosure. Please refer to FIG. 10. The difference between a display apparatus 10A of the embodiment and the display apparatus 10 of FIG. 1C is that the structure of the flexible circuit board near the openings is different. For example, in the embodiment, a flexible circuit board 200B of the display apparatus 10A further includes a first connection section 200c1 extending from the first part 200p1, a second connection section 200c2 and a third connection section 200c3 extending from the second part 200p2, and a fourth connection section 200c4 extending from the third part 200p3. The first connection section 200c1 is connected to the second connection section 200c2. The third connection section 200c3 is connected to the fourth connection section 200c4.

It should be noted that in the embodiment, the first extension section 200e1, the second extension section 200e2, the first connection section 200c1, the second connection section 200c2, the first part 200p1, and the second part 200p2 define an opening OP1-A, and the first connection section 200c1 and the second connection section 200c2 are located between the opening OP1-A and the display panel 100. Similarly, the third extension section 200e3, the fourth extension section 200e4, the third connection section 200c3, the fourth connection section 200c4, the second part 200p2, and the third part 200p3 define an opening OP2-A, and the third connection section 200c3 and the fourth connection section 200c4 are located between the opening OP2-A and the display panel 100.

In other words, the opening OP1-A of the flexible circuit board 200B of the embodiment does not expose the junction of the first side edge 100e1 and the second side edge 100e2 of the display panel 100, and the opening OP2-A does not expose the junction of the second side edge 100e2 and the third side edge 100e3 of the display panel 100. It is particularly noted that similar to the first extension section 200e1 and the second extension section 200e2, a signal wire (not shown) extending from the second part 200p2 may also extend to the first part 200p1 via the first connection section 200c1 and the second connection section 200c2 of the embodiment or extend to the third part 200p3 via the third connection section 200c3 and the fourth connection section 200c4, so as to further increase the layout flexibility of the peripheral wires.

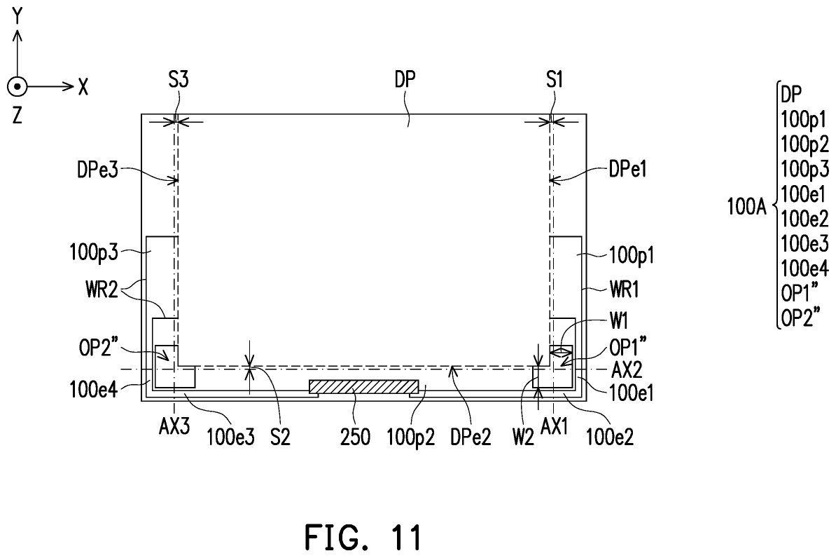

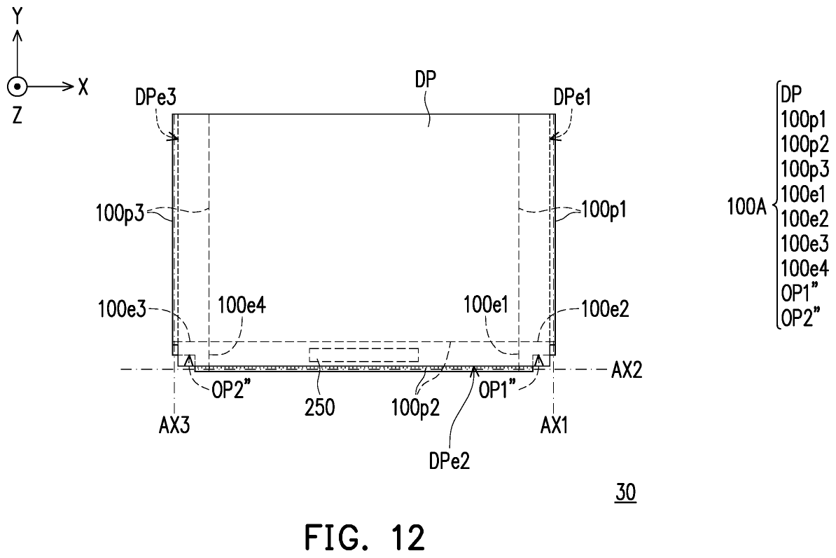

FIG. 11 and FIG. 12 are schematic front views of a display apparatus according to a fifth embodiment of the disclosure. Please refer to FIG. 11 and FIG. 12. Different from the display apparatus 10 of FIG. 1C, in the embodiment, the driving chip 250, the signal wires WR1 and the signal wires WR2 of the display apparatus 30 are disposed on the display panel 100A.

In detail, the display panel 100A has a display portion DP and a peripheral portion. The display portion DP has a first side edge DPe1, a second side edge DPe2 and a third side edge DPe3. The first side edge DPe1 is adjacent to the second side edge DPe2, and is opposite to the third side edge DPe3 along the direction X. More specifically, the second side edge DPe2 is connected between the first side edge DPe1 and the third side edge DPe3.

The peripheral portion includes a first part 100p1 extending from the first side edge DPe1, a second part 100p2 extending from the second side edge DPe2 and a third part extending from the third side edge DPe3. For example, in the embodiment, the display panel 100A may be a flexible display panel. The first part 100p1 of the peripheral portion is bent along a first bending axis. The second part 100p2 of the peripheral portion is bent along a second bending axis. The third part 100p3 of the peripheral portion is bent along a third bending axis.

It is similar to the display apparatus 10 of FIG. 1A and FIG. 1C that the intersection of the first bending axis AX1 and the second bending axis AX2 overlaps with the opening OP1″, and the intersection of the second bending axis AX2 and the third bending axis AX3 overlaps with the opening OP2″. In the embodiment, the opening OP1″ of the peripheral portion exposes a junction of the first side edge DPe1 and the second side edge DPe2 of the display portion DP. The opening OP2″ of the peripheral portion exposes a junction of the second side edge DPe2 and the third side edge DPe3 of the display portion DP.

From another point of view, a minimum width W1 of the opening OP1″ along the direction X is greater than the first spacing S1 between the first bending axis AX1 and the first side edge DPe1 of the display portion DP in the direction X, so that the first bending axis AX1 can pass through the opening OP1″. A minimum width W2 of the opening OP1″ along the direction Y is greater than the second spacing S2 between the second bending axis AX2 and the second side edge DPe2 of the display portion DP in the direction Y, so that the second bending axis AX2 can pass through the opening OP1″. Since the relative relationship between the minimum widths of the opening OP2″ in different directions and the second spacing S2 and the third spacing S3 is similar to the design principle of the opening OP1″, detail will not be repeated here.

In the embodiment, the peripheral portion of the display panel 100A further includes a first extension section 100e1 extending from the first part 100p1, a second extension section 100e2 and a third extension section 100e3 extending from the second part 100p2, and fourth extension section 100e4 extending from the third part 100p3. The first extension section 100e1 is connected to the second extension section 100e2 and is structurally separated from the display portion DP. The third extension section 100e3 is connected to the fourth extension section 100e4 and is structurally separated from the display portion DP.

From another point of view, the first part 100p1, the second part 100p2, the first extension section 100e1, and the second extension section 100e2 define the opening OP1″ of the display panel 100A. The second part 100p2, the third part 100p3, the third extension section 100e3, and the fourth extension section 100e4 define the opening OP2″ of the display panel 100A (as shown by the peripheral portion of the display panel 100A before being bent in FIG. 11).

In the embodiment, the second part 100p2 of the peripheral portion may be provided with a driving chip 250, and the driving chip 250 is, for example, a source integrated circuit (IC), a gate IC, or other driving chips with different functions, but not limited thereto. It should be noted that a part of the signal wire WR1 on the second part 100p2 of the peripheral portion may extend to the first part 100p1 via the first extension section 100e1 and the second extension section 100e2, and another part of the signal wire WR2 may extend to the third part 100p3 via the third extension section 100e3 and the fourth extension section 100e4 (as shown in FIG. 11).

Since the display panel 100A is flexible, the peripheral portion of the display portion DP is adapted to be folded up and is fixed on the rear side of the display portion DP, which facilitates the implementation of an ultra-narrow border or borderless appearance design of the display apparatus 30.

The configuration of the openings can effectively reduce excessive deformation that affects the normal operation (for example, the transmission of electrical signals) of the signal wires disposed on the peripheral portion generated at a junction of the two adjacent parts (for example, the first part 100p1 and the second part 100p2 or the second part 100p2 and the third part 100p3) of the peripheral portion when two parts are bent.

Since the folding process of the peripheral portion of the display panel 100A is similar to that of the flexible circuit board 200 electrically bonded to the display panel 100 of FIG. 1A, the description of the same technical content will be omitted. For the omitted part, please refer to the foregoing embodiment, and there will be no reiteration below.

In summary, in the display apparatus according to an embodiment of the disclosure, the two parts of the flexible circuit board bonded to the two adjacent sides of the display panel are respectively bent along the two bending axes intersecting each other. Through configuring the openings at the intersection of the two bending axes, excessive deformation that affects the normal operation of the flexible circuit board generated at the junction of the two parts of the flexible circuit board when the two parts are bent can be effectively reduced.

What is claimed is:

1. A display apparatus, comprising:
a display panel, having a first side and a second side adjacent to each other; and
a flexible circuit board, comprising a first part and a second part connected to each other, wherein the first part is electrically bonded to the first side of the display panel, the second part is electrically bonded to the second side of the display panel, the first part of the flexible circuit board is bent along a first bending axis, and the second part of the flexible circuit board is bent along a second bending axis,
wherein the flexible circuit board is provided with an opening, and an intersection of the first bending axis and the second bending axis overlaps with the opening.

2. The display apparatus according to claim 1, wherein the display panel has a first side edge located on the first side and a second side edge located on the second side, and the opening of the flexible circuit board exposes a junction of the first side edge and the second side edge.

3. The display apparatus according to claim 1, wherein the flexible circuit board further comprises a first extension section extending from the first part and a second extension section extending from the second part, and the first extension section is connected to the second extension section and is structurally separated from the display panel, wherein at least one signal wire of the first part extends to the second part via the first extension section and the second extension section.

4. The display apparatus according to claim 3, wherein the flexible circuit board further comprises a first connection section extending from the first part and a second connection section extending from the second part, the first connection section is connected to the second connection section and is located between the opening and the display panel, and the first extension section, the second extension section, the first connection section, the second connection section, the first part, and the second part define the opening.

5. The display apparatus according to claim 1, wherein the display panel has a first side edge located on the first side, there is a first spacing between the first bending axis and the first side edge of the display panel in a first direction, and a minimum width of the opening of the flexible circuit board along the first direction is greater than the first spacing.

6. The display apparatus according to claim 5, wherein the display panel also has a second side edge located on the second side, there is a second spacing between the second bending axis and the second side edge of the display panel in a second direction, and a minimum width of the opening of the flexible circuit board along the second direction is greater than the second spacing.

7. The display apparatus according to claim 6, wherein each of the first spacing and the second spacing is less than or equal to 0.1 mm.

8. The display apparatus according to claim 1, wherein the display panel also has a display surface, the first part of the flexible circuit board is located on a side of the display panel away from the display surface, the first part overlaps with and is parallel to the display surface, and an angle between the second part of the flexible circuit board and the display surface is greater than or equal to 90 degrees.

9. A method of fabricating a display apparatus, comprising:
performing a bonding process to bond a flexible circuit board to a first side and a second side of a display panel, wherein the first side is adjacent to the second side, the flexible circuit board comprises a first part bonded to the first side, a second part bonded to the second side, and an opening, and the first part is connected to the second part;
bending the first part of the flexible circuit board by 180 degrees along a first bending axis, wherein the first bending axis passes through the opening; and
bending the second part of the flexible circuit board at an angle along a second bending axis, wherein the angle is greater than or equal to 90 degrees, and the second bending axis passes through the opening.

10. The method of fabricating the display apparatus according to claim 9, wherein the angle is 180 degrees.

11. The method of fabricating the display apparatus according to claim 9, wherein the flexible circuit board further comprises a first extension section extending from the first part and a second extension section extending from the second part, the first extension section is connected to the second extension section, and at least one signal wire of the first part extends to the second part via the first extension section and the second extension section.

12. The method of fabricating the display apparatus according to claim 11, wherein after bending the first part of the flexible circuit board by 180 degrees, the first extension section overlaps with the second part.

13. The method of fabricating the display apparatus according to claim 12, wherein after bending the second part of the flexible circuit board by 180 degrees, the second extension section overlaps with the first part.

14. The method of fabricating the display apparatus according to claim 13, wherein a bending step of the second part is performed after completing a bending step of the first part, so that the first extension section is located between the first part and the second part.

15. The method of fabricating the display apparatus according to claim 11, wherein after bending the first part of the flexible circuit board by 180 degrees, the second part of the flexible circuit board is bent by 90 degrees.

16. A display apparatus, comprising:
a display panel, having a display portion and a peripheral portion, wherein the display portion has a first side edge and a second side edge adjacent to each other, the peripheral portion includes a first part extending from the first side edge of the display portion and a second part extending from the second side edge of the display portion, the first part of the peripheral portion is bent along a first bending axis, and the second part of the peripheral portion is bent along a second bending axis,
wherein the peripheral portion is provided with an opening, and an intersection of the first bending axis and the second bending axis overlaps with the opening.

17. The display apparatus according to claim 16, wherein the opening of the peripheral portion exposes a junction of the first side edge and the second side edge.

18. The display apparatus according to claim 16, wherein the peripheral portion further comprises a first extension section extending from the first part and a second extension section extending from the second part, the first extension section is connected to the second extension section and is structurally separated from the display portion, wherein at least one signal wire of the first part extends to the second part via the first extension section and the second extension section.

19. The display apparatus according to claim 16, wherein a first spacing is provided between the first bending axis and the first side edge of the display portion in a first direction, and a minimum width of the opening of the peripheral portion along the first direction is greater than the first spacing.

20. The display apparatus according to claim 19, wherein a second spacing is provided between the second bending axis and the second side edge of the display portion in a second direction, and a minimum width of the opening of the peripheral portion along the second direction is greater than the second spacing.
